(19) United States
(12) Patent Application Publication
(10) Pub. No.: US 2006/0220223 A1
(43) Pub. Date: Oct. 5, 2006

(54) Reactive nano-layer material for MEMS packaging

(76) Inventors: Daoqiang Lu, Chandler, AZ (US); John Heck, Berkeley, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/092,054

(22) Filed: Mar. 29, 2005

(51) Int. Cl. H01L 23/12

(52) U.S. Cl. 257/704; 257/E23.193

(57) ABSTRACT

According to one embodiment an apparatus and method for MEMS packaging including a reactive nano-layer is presented. The apparatus comprises a substrate, an environmentally sensitive device on the substrate, a cap to fit over the device, and a hermetic seal between the cap and the substrate. The hermetic seal comprises a solder layer, and a reactive layer including one or more elements that react together through an initiating energy to emit exothermic heat to melt the solder layer.

### FIELD OF THE INVENTION

The present embodiments of the invention relate generally to micro-electromechanical systems (MEMS) packaging and, more specifically, relate to reactive nano-layer material for MEMS packaging.

### BACKGROUND

Micro-electromechanical systems (MEMS) devices have a wide variety of applications and are prevalent in commercial products. MEMS components such as varactors, switches, and resonators may be environmentally sensitive and prone to contamination. For this reason, and particularly with radio frequency (RF) MEMS components, there may be a need for hermetic packaging. Such packaging protects the MEMS components from the outside environment. Further, the sealing materials should not give off any volatiles which themselves may contaminate the MEMS device.

Conventionally, several approaches have been utilized for hermetic packaging of MEMS components. Such approaches include fluxless soldering, thermocompression bonding, eutectic bonding, and glass frit bonding.

Fluxless soldering is a process where solder reflow and joining can be effectively performed without flux in air or in nitrogen. For example, this process may use a gold-tin (Au 80%/Sn20%) solder. This process eliminates flux, flux dispensing, flux cleaning and cleaning solvents, and disposal of the spent chemicals. However, fluxless soldering using a gold-tin solder utilizes a high processing temperature, such as between 300° C. and 310° C. Other fluxless solders are not suitable for MEMS packaging because they reflow at lower temperatures, so they would not survive the process to assemble the packaged MEMS device to the board.

Thermocompression bonding joins two surfaces, such as a MEMS wafer and a cap wafer, via the welding of soft metals on each surface. The most common metal used for MEMS applications is gold (Au), with a suitable adhesion layer. However, thermocompression bonding may be slow, and it relies on expensive and thick gold electroplating.

Eutectic bonding utilizes a two-component system to form bonding between two wafers, such as a MEMS wafer and a cap wafer, by coating one of the wafers with one component of the system and the other wafer with the second component. When the wafers are heated and brought into contact, diffusion occurs at the interface and alloys are formed. The eutectic composition alloy formed at the interface has a lower melting point that the materials either side of it, and hence the melting is restricted to a thin layer. However, eutectic bonding requires a high processing temperature, generally greater than 360° C., such as that required for the fold-silicon eutectic system.

Glass frit bonding uses a glass frit to bond a wafer containing the MEMS component to a cover. This technique uses bonding at temperatures in the range of 350-500° C. that may not be suitable for all components utilized in some MEMS applications. In some cases, the glass frit occupies a large area that increases the size of the resulting product and therefore increases its costs. Also, the glass frit bonding technology may use wire bonds for electrical connections that may not be adequate in some applications, such as high frequency applications.

Each of these bonding approaches has disadvantages, such as high processing temperatures, high cost, or lengthy time.

### BRIEF DESCRIPTION OF THE DRAWINGS

The present invention will be understood more fully from the detailed description given below and from the accompanying drawings of various embodiments of the invention. The drawings, however, should not be taken to limit the invention to the specific embodiments, but are for explanation and understanding only.

FIG. 1 illustrates one embodiment of a top view of a MEMS switch device;

FIG. 2 illustrates one embodiment of a side view of a MEMS switch device;

FIG. 3 illustrates one embodiment of a side view of a MEMS device prior to being hermetically sealed;

FIG. 4 illustrates one embodiment of a side view of a hermetically sealed MEMS device;

FIG. 5 illustrates one embodiment of a top view of an array of MEMS devices prior to being hermetically sealed;

FIG. 6 illustrates one embodiment of a side view of an array of MEMS die; and

FIG. 7 is a flow diagram depicting a method according to one embodiment of the present invention.

### DETAILED DESCRIPTION

An apparatus and method to package a MEMS device is described. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

In the following description, numerous details are set forth. It will be apparent, however, to one skilled in the art, that the embodiments of the invention may be practiced without these specific details. In other instances, well-known structures and devices are shown in block diagram form, rather than in detail, in order to avoid obscuring the present invention.

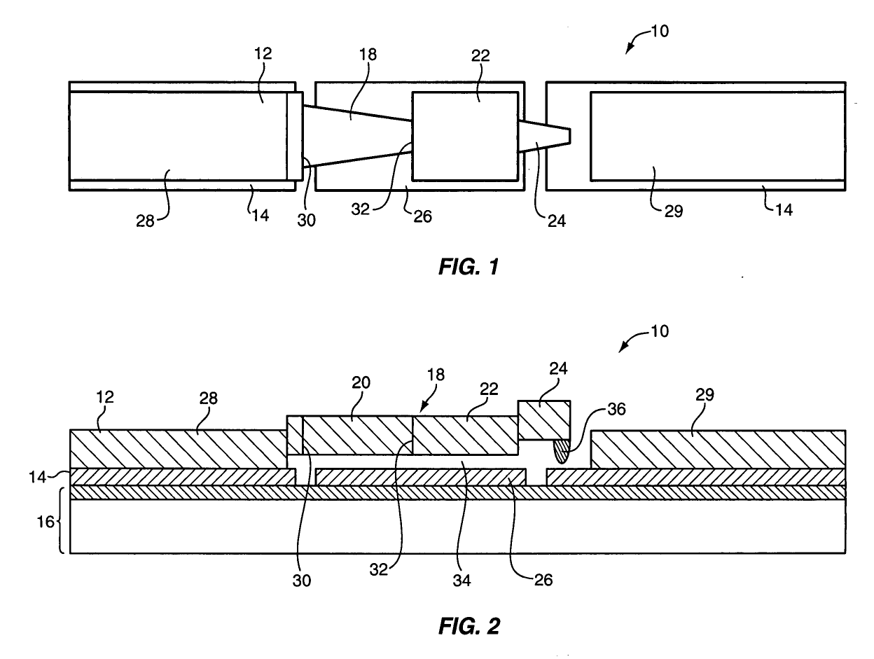

Referring to FIGS. 1 and 2, these figures illustrate a top view and a side view of a microelectromechincal system (MEMS) cantilever series switch, respectively. The MEMS switch is used as an illustration of embodiments of the invention that may be applied to other types of MEMS components, such as varactors or resonators that are to be packaged in a hermetic environment.

As shown, the series switch 10 includes an anchor 12 mounted to a dielectric pad 14 attached to a substrate 16, and a cantilever beam 18 that includes a tapered portion 20, an actuation portion 22, and a tip 24. An actuation electrode 26 is mounted to the substrate 16 and positioned between the actuation portion 22 of the beam and the substrate 16.

The anchor 12 is firmly attached to a dielectric pad 14.positioned on the substrate 16. As its name implies, the anchor provides a firm mechanical connection between the beam 18 and the substrate 16, as well as providing a rigid structure from which the beam 18 is cantilevered, and providing electrical connection between the beam 18 and the substrate 16.

In the embodiment shown, the anchor 12 is a first portion 28 of a signal line carrying some form of electrical signal. The anchor 12 is thus made of an electrically conductive material to allow it to carry the signal and transmit it into the beam 18 during operation of the switch 10. The substrate 16 can, for example, be some sort of semiconductor wafer or some portion thereof comprising various layers of different semi-conducting material, such as polysilicon, single crystal silicon, etc., although the particular construction of the substrate 16 is not important to the construction or function of the apparatus described herein.

The tapered portion 20 of the beam 18 includes a proximal end 30 and a distal end 32. The proximal end 30 is attached to the anchor 12, while the distal end 32 is attached to the actuation portion 22. The tapered portion 20 of the beam 18 is vertically offset relative to the anchor 12 to provide the needed space 34 between the actuation portion 22 and the actuation electrode 26. The tapered portion 20 of the beam 18 is relatively thick (approximately 6 μm) and made of a highly conductive material such as gold (Au), although in some embodiments it can be made of other materials or combinations of materials, or can have a composite construction. The gap 34 between the actuation electrode 26 and the actuation portion 22 of the beam 18 is on the order of 5 μm, although in other embodiments a greater or lesser gap can be used.

The actuation portion 22 is mounted to the distal end 32 of the tapered portion 20 of the beam 18. The actuation portion 22 is relatively wide compared to the tapered portion 20, to provide a greater area over which the force applied by the activation of the actuation electrode 26 can act. In other words, since actuation force is proportional to the area of the actuation portion 22, the wider and longer actuation portion 22 of the beam 18 causes a larger force to be applied to the beam 18 when the actuation electrode 26 is activated. This results in faster switch response. Like the tapered portion 20, the actuation portion 22 is also preferably made of some highly conductive material such as gold, although in some embodiments it can be made of other materials or combinations of materials, or can have a composite construction.

A tip 24 is attached to the actuation portion 22 of the beam 18 opposite from where the tapered portion 20 is attached. On the lower side of the tip 24 there is a contact dimple 36, whose function is to make contact with the electrode 29 when the cantilever beam 18 deflects in response to a charge applied to the actuation electrode 26. The tip 24 is vertically offset from the actuation area 22, much like the tapered portion 20 is offset vertically from the anchor 12. This vertical offset of the tip 24 relative to the actuation area 22 reduces capacitative coupling between the beam 18 and the second portion 29 of the signal line.

In operation of the switch 10, the anchor 12 is in electrical contact with, and forms part of, a first portion 28 of a signal line carrying an electrical signal. Opposite the first portion 28 of the signal line is a second portion 29 of the signal line. To activate the switch 10 and make the signal line continuous, such that a signal traveling down the first portion 28 of the signal line will travel through the switch 10 and into the second portion 29 of the signal line, the actuation electrode 26 is activated by inducing a charge in it.

When the actuation electrode 26 becomes electrically charged, because of the small gap between the actuation electrode 26 and the actuation portion 22 of the beam 18, the actuation portion 22 of the beam will be drawn toward the electrode. When this happens, the beam 18 deflects downward, bringing the contact dimple 36 in contact with the second electrode 29, thus completing the signal line and allowing a signal to pass from the first portion 28 of the signal line to the second portion 29 of the signal line.

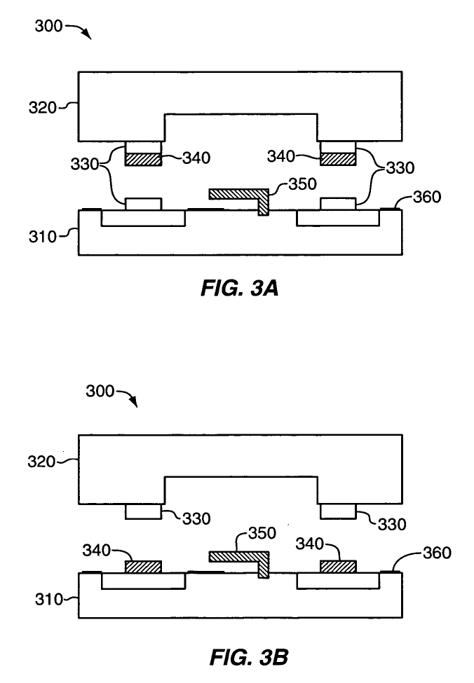

Referring now to FIGS. 3A and 3B, these figures are schematic diagrams illustrating a MEMS device 300 prior to being hermetically sealed. In one embodiment MEMS device 300 may be switch 10 as discussed above with respect to FIGS. 1 and 2. The MEMS device 300 includes a switch 350. The MEMS switch 350 may be formed on a semiconductor substrate 310. One skilled in the art will appreciate that MEMS device 300 may include another MEMS component, such as a resonator or a varactor, and is not limited to a switching device as illustrated.

A cap wafer 320 may be bonded to the semiconductor substrate 310 through sealing materials 330 and 340 in order to enclose the MEMS switch 350. The sealing materials 330 and 340, once bonded together, may be in the form of a ring or closed loop that encases the MEMS switch 350 in a hermetically sealed area. One or more electrical conductors 360 may extend through the semiconductor substrate to the exterior of the MEMS device 300.

In embodiments of the present invention, sealing materials 330 and 340 are bonded together to form a hermetic seal encasing a MEMS device. In one embodiment, sealing material 330 is a solder material, while sealing material 340 includes multiple nano-layers of reactive material. The reactive nano-layer material of sealing material 340 includes one or more elements or compounds that react through an initiating energy source to form a stable compound while emitting exothermic heat. In one embodiment, the one or more elements or compounds of the reactive nano-layer material are alternatively layered with one another, with each layer measuring in the nano-meter range.

In one embodiment of the present invention, the reactive nano-layer material of sealing material 340 reacts through an initiating energy to produce a large exothermic heat that rapidly propagates throughout the reactive nano-layer material 340. The solder material of sealing material 330 melts due to the exothermic heat given off by the reaction of the nano-layer material 340, and in this manner creates a unified seal between the semiconductor substrate 310 and the cap wafer 320 that encases the MEMS device 350 in a hermetically sealed area.

FIG. 3A illustrates one embodiment of a MEMS device 300 with a deposit of solder material 330 and reactive nano-layer material 340. Solder material 330 may be deposited on both the semiconductor substrate 310 and the cap wafer 320. Reactive nano-layer material 340 may be deposited on the solder material 330 of cap wafer 320. Alternatively, in another embodiment, reactive nano-layer material 340 may be deposited on the solder material 330 located on the semiconductor substrate 310.

FIG. 3B illustrates another embodiment of a MEMS device 300 with deposits of solder material 330 and reactive nano-layer material 340. Solder material 330 and reactive nano-layer material 340 may each be deposited independently of each other on either wafer. For example, solder material 330 may be deposited on the cap wafer 320 while reactive nano-layer material 340 is deposited opposite the solder material 330 on the semiconductor substrate 310. In another embodiment, the solder material 330 may be deposited on the semiconductor substrate 310 while the reactive nano-layer material 340 is deposited on the cap wafer 320 directly opposite the solder material 330.

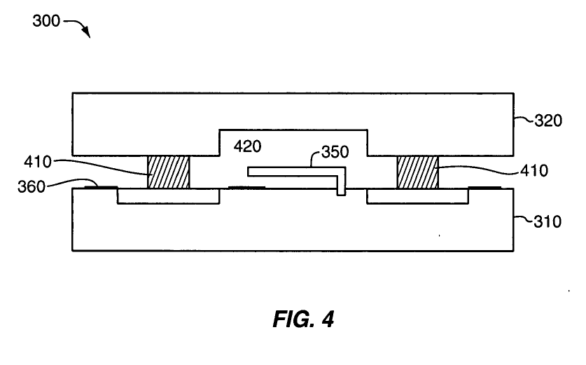

FIG. 4 illustrates a schematic diagram of one embodiment of a MEMS device 300, as described with respect to FIGS. 3A and 3B, after being hermetically sealed. Sealing ring 410 is the result of the bonding of solder material 330 and reactive nano-layer material 340 after an initiating energy was applied to the reactive nano-layer material 340 to create an exothermic heat-producing reaction to melt the solder material 330. Once sealed, the MEMS switch 350 is encased in a hermetically sealed area 420.

The reactive nano-layer material 340 may generally include any two or more elements or compounds that create a self-sustaining reaction through a quick initiating energy source. The reaction of the nano-layer elements or compounds also should produce a large amount of exothermic heat capable of melting a solder material. In one embodiment the reaction propagates rapidly (in the millisecond range) throughout the nano-layer material. Furthermore, the reaction completes quickly, thereby containing the exothermic heat to the localized area of the sealing materials.

Self-sustaining reactions may be maintained in pairs of elements including, but not limited to: Titanium (Ti)/Boron (B); Nickel (Ni)/Silicon (Si); Zirconium (Zr)/Si; Rhodium (Rh)/Si; Ni/Aluminum (Al); and Palladium (Pd)/Al. One skilled in the art will appreciate that other suitable materials may exist that exhibit the necessary qualities to satisfy requirements of embodiments of the invention. Furthermore, although examples listed here contain two elements, one skilled in the art will appreciate that self-sustaining reactions may be maintained in groups of one or more elements or compounds and is not limited to two elements.

The Table 1 below shows exemplary reactive nano-layer material, the resultant reaction compound, and the corresponding heat of reaction.

TABLE 1

| Materials | Reaction Compound | Heat of Reaction (kJ mol⁻¹) |
|---|---|---|
| Titanium/2 Boron | TiB₂ | −108 |
| 2 Nickel/Silicon | Ni₂Si | −48 |
| Nickel/Aluminum | NiAl | −46 |
| Palladium/Aluminum | PdAl | −92 |
| Zirconium/2 Boron | ZrB₂ | −108 |

Embodiments of the invention feature an initiating energy source to begin the reaction in the nano-layer material. Examples of an initiating energy include radiation from a laser, heat from a filament, impact from a sharp stylus, and a spark from an electrical source. One skilled in the art will appreciate that there are a variety of sources that can produce the necessary energy to initiate a reaction in reactive nano-layer materials.

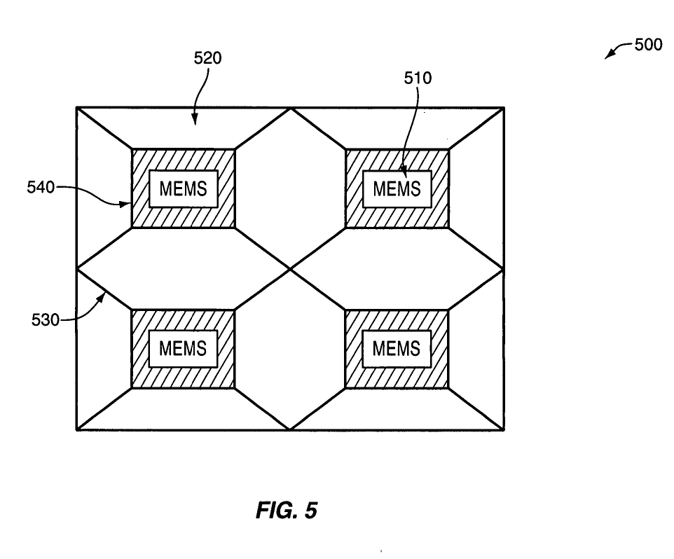

FIG. 5 illustrates a schematic diagram of one embodiment of an array of MEMS die 500. Typically, MEMS devices 510 are produced in bulk on a single substrate 520, and then diced to form a single MEMS device 510. In one embodiment of the present invention, the solder material and the reactive nano-layer material may be deposited on the substrate wafer to form sealing rings 540 around each individual MEMS device.

Furthermore, the solder material and the reactive nano-layer material may be deposited to form connections 530 between the sealing rings on the substrate 520. These connections 530 allow the reaction of the nano-layer material to propagate throughout the interface of the nano-layer material of the sealing rings 540 encasing the plurality of MEMS devices 510 on the substrate wafer 520. In one embodiment, the initiating energy source only has to be applied to one edge of the reactive nano-layer material in order to bond the plurality of MEMS devices.

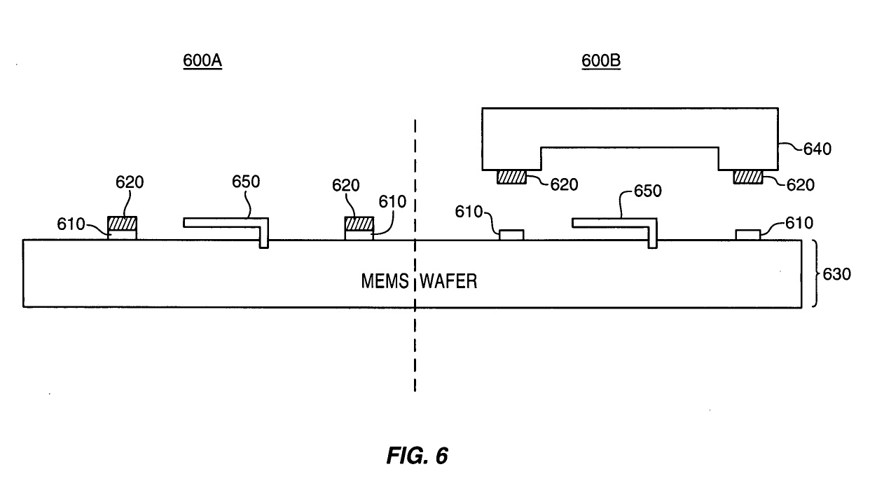

Referring to FIG. 6, an array of MEMS die may be created on a single substrate or wafer 630. In one embodiment, a first MEMS die 600A may be manufactured directly adjacent another MEMS die 600B. As shown, the MEMS die 600A and 600B may include a MEMS device 650, such as a switch as illustrated. In other embodiments, MEMS device 650 may comprise other types of MEMS devices and is not limited to a switching device.

MEMS die 600A and 600B also include substrate sealing materials 610 and 620 comprising the solder and reactive nano-layer materials described above. In addition, a cap wafer 640 may include the sealing materials 610 and 620. While the cap wafer 640 is shown as a single cap, it may be appreciated that the cap wafer 640 may also comprise a wafer level array of caps for capping both die 600A and 600B at once. The MEMS die 600A and 600B may later be singulated in a dicing process.

FIG. 7 is a flow diagram illustrating a method according to one embodiment of the present invention. The method is one embodiment of hermetically sealing a MEMS device using reactive nano-layer materials. The process begins at processing block 710 where solder rings are deposited on a cap wafer. Then, at processing block 720, a reactive nano-layer material is deposited on the solder material on the cap wafer, or alternatively on the MEMS wafer. One skilled in the art will appreciate that any of the variety of deposit arrangements of the solder material and the reactive nano-layer material described earlier may be utilized.

At processing block 730, the MEMS wafer and the cap wafer are aligned using a wafer aligner. At processing block 740, pressure is applied to the MEMS wafer and the cap wafer in a bonding chamber. Then, at processing block 750, the nano-layer material is activated in the bonding chamber through an initiating energy source. At processing block 760, the reaction propagates throughout the nano-layer material, and, at processing block 770, the solder material is melted by the exothermic heat created by the nano-layer material reaction, thereby creating a hermitically sealed MEMS device. Finally, at processing block 780, the bonded wafers may be diced into single MEMS packages.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the invention.

What is claimed is:

1. An apparatus, comprising:
a substrate;
an environmentally sensitive device on the substrate;
a cap to fit over the device; and
a hermetic seal between the cap and the substrate, the hermetic seal comprising:
a solder layer; and
a reactive layer including one or more elements that react together to emit exothermic heat to melt the solder layer.

2. The apparatus of 1, wherein the one or more elements of the reactive layer are alternatively deposited in nanoscale layers ranging from 1 to 1000 nm thickness.

3. The apparatus of claim 1, wherein the one or more elements of the reactive layer react together through an initiating energy including at least one of the following: radiation from a laser, heat from a filament, impact from a sharp stylus, and a spark from an electrical source.

4. The apparatus of claim 1, wherein the reaction between the one or more elements of the reactive layer propagates throughout the reactive layer in the millisecond range.

5. The apparatus of claim 1, wherein the one or more elements of the reactive layer comprise Titanium (Ti) and Boron (B).

6. The apparatus of claim 1, wherein the one or more elements of the reactive layer comprise Nickel (Ni) and Silicon (Si).

7. The apparatus of claim 1, wherein the one or more elements of the reactive layer comprise Palladium (Pd) and Aluminum (Al).

8. The apparatus of claim 1, wherein the one or more elements of the reactive layer comprise Zirconium (Zr) and Boron (B).

9. The apparatus of claim 1, wherein the reactive layer further includes one or more connections to a reactive layer of a second hermetic sealing ring between a second cap and the substrate enclosing a second environmentally sensitive device.

10. A method, comprising:
depositing a solder material on a first wafer;
depositing a reactive material on at least one of the first wafer and a second wafer;
applying an initiating energy to the reactive material to create a reaction in the reactive material; and
forming a sealing ring between the first wafer and the second wafer by melting the solder material with exothermic heat emitted from the reaction of reactive material.

11. The method of claim 10, further comprising dicing the sealed first and second wafers into a single die.

12. The method of claim 10, wherein the first wafer is a micro-electromechanical system (MEMS) wafer including a MEMS device and the second wafer is a cap wafer.

13. The method of claim 10, wherein the first wafer is a cap wafer and the second wafer is a micro-electromechanical system (MEMS) wafer including a MEMS device.

14. The method of claim 10, wherein the initiating energy is at least one of the following: radiation from a laser, heat from a filament, impact from a sharp stylus, and a spark from an electrical source.

15. The method of claim 10, wherein the applying an initiating energy to the reactive material is performed in a bonding chamber.

16. The method of claim 10, wherein the reactive material includes one or more elements alternatively deposited in nanoscale layers ranging from 1 to 1000 nm thickness.

17. A hermetically sealed micro-electromechanical system (MEMS), comprising:
a MEMS device disposed on a substrate;
a cap to fit over the MEMS device; and
a hermetic sealing ring formed between the cap and the substrate, the sealing ring comprising:
a solder layer; and
a reactive layer including one or more elements that react together to emit exothermic heat to melt the solder layer.

18. The hermetically sealed micro-electromechanical system (MEMS) of claim 17, wherein the one or more elements of the reactive layer are alternatively deposited in nanoscale layers ranging from 1 to 1000 nm thickness.

19. The hermetically sealed micro-electromechanical system (MEMS) of claim 17, wherein the one or more elements of the reactive layer react together through an initiating energy including at least one of the following: radiation from a laser, heat from a filament, impact from a sharp stylus, and a spark from an electrical source.

20. The hermetically sealed micro-electromechanical system (MEMS) of claim 17, wherein the reaction between the one or more elements of the reactive layer propagates throughout the reactive layer in the millisecond range.
